(19) United States
(12) Patent Application Publication
(10) Pub. No.: US 2024/0332121 A1
(43) Pub. Date: Oct. 3, 2024

(54) ELECTRICALLY-INSULATING AND HIGHLY THERMAL CONDUCTIVE SHEET FOR ELECTRONIC DEVICES

(71) Applicant: International Business Machines Corporation, Armonk, NY (US)

(72) Inventors: Mukta Ghate Farooq, Hopewell Junction, NY (US); John Knickerbocker, Monroe, NY (US); Keiji Matsumoto, Yokohama-shi (JP)

(21) Appl. No.: 18/128,745

(22) Filed: Mar. 30, 2023

(51) Int. Cl. H01L 23/373

(52) U.S. Cl. CPC H01L 23/3735; H01L 23/3731; H05K 1/0204

(57) ABSTRACT

An electronic device in which an electrically-insulating and highly thermal conductive sheet is located at the interconnect level is provided. The presence of the electrically-insulating and highly thermal conductive sheet at the interconnect level provides a significant reduction in the temperature of the electronic device, without causing excess stress in the electronic device. This results in electronic devices that have improved performance and reliability.

### BACKGROUND

The present application relates to semiconductor technology, and more particularly to an electronic device including an electrically-insulating and highly thermal conductive sheet located at the interconnect level.

Electronic devices commonly include printed circuit boards on which electrical components, such as integrated circuit (IC's) and other types of electrical components, are mounted and connected in particular ways to provide desired functionalities. A common approach to mount an electrical component to a printed circuit board is to use solder. More particularly, a number of solder bumps may be applied to the printed circuit board and heated, such that an electrical component can then be disposed to the solder bumps to affix the component to the circuit board.

Unfortunately, this approach to mounting electrical components to printed circuit boards can be problematic. Stresses can result from the differences in the coefficient of thermal expansion (CTE) of an electrical component and the CTE of solder, as well as from differences in the CTE of a printed circuit board and the CTE of the solder. During use of such an electrical device, for instance, if these stresses become too high, the solder may crack, causing the electrical component to no longer be properly affixed to the printed circuit board.

One solution to alleviate this problem is to include an underfill film between the electrical component and the printed circuit board of an electronic device. The underfill film itself relaxes the stresses resulting from CTE differences of the solder and the electrical component and the printed circuit board. Such stresses are thus absorbed by the film, instead of by the solder, reducing the likelihood that the electrical component may break away from the printed circuit board.

Another issue within electronic device design is the dissipation of heat. Modern IC's, for instance, can generate significant amounts of heat, which if not properly dissipated can cause failure of their electronic devices. Furthermore, electronic devices have become increasingly smaller, leading to printed circuit boards that are closely packed with electrical components. This means that using heat sinks for heat dissipation, as is conventional, can become problematic, because they may not be able to be located near the electrical components that require heat dissipation.

One solution is to add solder bumps, or balls, to the underside of a printed circuit board, which serve to dissipate heat through the printed circuit board. This approach is not overly effective, however, because the printed circuit board itself is usually not a good thermal conductive, such that the printed circuit board itself becomes a thermal insulator. Therefore, another approach, either alone or in combination with solder bumps on the underside of a printed circuit board, is to use the printed circuit board itself as a type of heat sink to dissipate heat. However, in order for a printed circuit board to effectively dissipate heat, there must be a thermally conductive path between the electrical components and the printed circuit board in the first place. Unfortunately, the inclusion of underfill films between the components and a printed circuit board effectively results in the components being thermally insulated from the printed circuit board. That is, most underfill films are made of a resin or another material that has low thermal conductivity. Therefore, heat does not efficiently travel from the electrical components to the printed circuit board.

A limited solution is to mix materials with high thermal conductivity into the underfill film material itself to improve thermal conductivity. For example, an underfill is available that includes aluminum particles mixed into a resin to improve the thermal conductivity of the resulting underfill film. However, this solution only transfers heat to the printed circuit board itself. Even a printed circuit board with a high thermal conductivity still has a thermal conductivity lower than most heat sinks, for instance, and therefore additional heat dissipation may be required. For instance, the printed circuit boards described above using thermally conductive resins still have relatively low thermal conductivity as compared to heat sinks.

Underfill films composed of a thermally conductive sheet have been disclosed, see for example, U.S. Patent Application Publication No. 2008/0067670. However, the use of thermally conductive sheets is problematic since the itself sheet is electrically conductive, but not electrically insulating.

### SUMMARY

An electronic device in which an electrically-insulating and highly thermal conductive sheet at located at the interconnect level is provided. The presence of the electrically-insulating and highly thermal conductive sheet at the interconnect level provides a significant reduction in the temperature of the electronic device (in some embodiments at least a 4° C. decrease in temperature of the electronic device is exhibited), without causing excess stress in the electronic device. This results in electronic devices that have improved performance and reliability.

In one aspect of the present application, an electronic device is provided. In one embodiment of the present application, the electronic device includes an electrically-insulating and highly thermal conductive sheet having a first surface and a second surface opposite the first surface, wherein the electrically-insulating and highly thermal conductive sheet is a perforated stack of a thermal conductive material-containing layer sandwiched between a first ceramic layer and a second ceramic layer. The electronic device further includes a packaging substrate located on the first surface of the electrically-insulating and highly thermal conductive sheet, and at least one semiconductor chip located on the second surface of the electrically-insulating and highly thermal conductive sheet.

In some embodiments of the present application, the electrically-insulating and highly thermal conductive sheet has a plurality of openings that extend from the first surface of the electrically-insulating and highly thermal conductive sheet to the second surface of the electrically-insulating and highly thermal conductive sheet.

In some embodiments of the present application, each of the openings is filled with solder.

In some embodiments of the present application, each of the openings is filled with an electrically conductive metal or an electrically conductive metal alloy.

In some embodiments of the present application, the first ceramic layer and the second ceramic layer are both composed of a same electrically insulating, yet thermally conductive, material.

In some embodiments of the present application, the first ceramic layer and the second ceramic layer are both composed of different electrically insulating, yet thermally conductive, material.

In some embodiments of the present application, the thermal conductive material-containing layer is composed of an electrically conductive metal, electrically conductive metal alloy or graphite.

In some embodiments of the present application, the first ceramic layer and the second ceramic layer are both composed of aluminum nitride (AlN), and the thermal conductive material-containing layer is composed of copper (Cu).

In some embodiments of the present application, the electronic device further includes a dielectric coating surrounding the perforated stack.

In some embodiments of the present application, the electronic device further includes a first non-conductive adhesive layer contacting the first ceramic layer and a portion of the packaging substrate, and a second non-conductive adhesive layer contacting the second ceramic layer and a portion of the semiconductor chip. In the present application, the non-conductive adhesives are composed of non-thermally conductive materials.

In some embodiments of the present application, the electronic device further includes first metal bond pads located on the packaging substrate and second metal bond pads located on the semiconductor chip, wherein the first metal bond pads and the second metal bond pads are aligned with each of the openings.

In some embodiments of the present application, the electronic device further includes a first solder layer located on each of the first metal bond pads and a second solder layer located on each of the second metal bond pads, wherein the first metal bond pads, the first solder layer, the second metal bond pads and the second solder layer are aligned with each of the openings.

In some embodiments of the present application, the packaging substrate is a laminate, an organic interposer, a silicon interposer or a glass interposer.

In some embodiments of the present application, the semiconductor chip is a plurality of stacked semiconductor chips.

In some embodiments of the present application, each stacked chip of the plurality is spaced apart by another electrically-insulating and highly thermal conductive sheet, wherein the another electrically-insulating and highly thermal conductive sheet is another perforated stack of another thermal conductive material-containing layer sandwiched between another first ceramic layer and another second ceramic layer.

In some embodiments of the present application, the electronic structure further includes a lid located on top of the semiconductor chip.

In some embodiments of the present application, the lid is composed of a thermal spreader material.

In some embodiments of the present application, the electrically-insulating and highly thermal conductive sheet comprises from 50 to 90 percent of the thermal conductive material-containing layer and the remainder of the electrically-insulating and highly thermal conductive sheet, up to 100 percent, comprises from 10 to 50 percent of the first ceramic layer and the second ceramic layer.

In some embodiments of the present application, the semiconductor chip is a high power semiconductor chip, such as for servers.

In some embodiments of the present application, the semiconductor chip is a low power semiconductor chip such as for mobile devices.

### BRIEF DESCRIPTION OF THE DRAWINGS

FIG. 1 is a cross sectional view illustrating an electrically-insulating and highly thermal conductive sheet that can be employed in one embodiment of the present application, the electrically-insulating and highly thermal conductive sheet having openings formed therein.

FIG. 2 is a cross sectional view of the electrically-insulating and highly thermal conductive sheet shown in FIG. 1 after forming a dielectric coating surrounding the electrically-insulating and highly thermal conductive sheet.

FIG. 3 is a cross sectional view of the dielectric coated electrically-insulating and highly thermal conductive sheet shown in FIG. 2 after forming an adhesive layer on one side of the dielectric coated electrically-insulating and highly thermal conductive sheet.

FIG. 4 is a cross sectional view of the dielectric coated electrically-insulating and highly thermal conductive sheet shown in FIG. 3 after attaching the adhesive layer of the dielectric coated electrically-insulating and highly thermal conductive sheet to a laminate containing metal bond pads.

FIG. 5 is a cross sectional view of the exemplary structure shown in FIG. 4 after filling each of the openings that are present in the dielectric coated electrically-insulating and highly thermal conductive sheet with solder.

FIG. 6 is a cross sectional view of a semiconductor chip containing metal bond pads and a non-conductive adhesive layer.

FIG. 7 is a cross sectional view of the exemplary structure shown in FIG. 5 after attaching the semiconductor chip shown in FIG. 6 thereto.

FIG. 8 is a cross sectional view of the dielectric coated electrically-insulating and highly thermal conductive sheet containing the adhesive layer as shown in FIG. 3 after forming a temporary metal sheet thereto.

FIG. 9 is a cross sectional view of the exemplary structure shown in FIG. 8 after filling each of the openings that are present in the dielectric coated electrically-insulating and highly thermal conductive sheet with an electrically conductive metal-containing material.

FIG. 10 is a cross sectional view of the exemplary structure shown in FIG. 9 after removing the temporary metal sheet.

FIG. 11 is a cross sectional view of a laminate that contains metal bond bands and a non-conductive adhesive layer.

FIG. 12 is a cross sectional view of the exemplary structure shown in FIG. 10 after attaching the laminate shown in FIG. 11 thereto.

FIG. 13 is a cross sectional view of the exemplary structure shown in FIG. 12 after attaching a semiconductor chip as shown in FIG. 6 thereto.

FIG. 14A is a cross sectional view of an electronic device that contains an electrically-insulating and highly thermal conductive sheet in accordance with the present application.

FIG. 14B is a top-down view showing the interconnect level containing the electrically-insulating and highly thermal conductive sheet of the device shown in FIG. 14A.

FIGS. 15A, 15B, 15C and 15D are cross sectional views illustrating other electronic devices that contain an electrically-insulating and highly thermal conductive sheet in accordance with the present application, in these electronic devices a heat spreader can be used for cooling.

FIGS. 16A and 16B are cross sectional views illustrating other electronic devices that contain an electrically-insulating and highly thermal conductive sheet in accordance with the present application, in these electronic devices heat is removed via the laminate.

FIGS. 17A, 17B and 17C are cross sectional views illustrating 3D stacked die electronic devices that contain an electrically-insulating and highly thermal conductive sheet in accordance with the present application, in these devices the electrically-insulating and highly thermal conductive sheet mitigates hot spots.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The present application provides electronic devices in which an electrically-insulating and highly thermal conductive sheet is located at the interconnect level. The term “interconnect level” is used throughout the present application to denote a level of the electronic device in which the semiconductor chip(s) (or die(s)) is(are) connected to a packaging substrate. In the present application, the connection between the packaging substrate and semiconductor chips is via the electrically-insulating and highly thermal conductive sheet of the present application. The term “highly thermal conductive” is used through the present application to denote that the sheet has a thermal conductivity of 100 W/mK or greater. In some embodiments, the thermal conductivity of the electrically-insulating and highly thermal conductive sheet is 145 W/mK or greater.

The electrically-insulating and highly thermal conductive sheet of the present application includes a perforated stack of a thermal conductive material-containing layer sandwiched between a first ceramic layer and a second ceramic layer. The first ceramic layer and the second ceramic layer are both electrically insulating, yet thermally conductive, materials. The presence of the electrically-insulating and highly thermal conductive sheet at the interconnect level provides a significant reduction in the temperature of the electronic devices (in some embodiments a reduction of 4° C. or more can be realized), without causing excess stress in the electronic devices. The stress is managed in the present application by selected materials from the electrically-insulating and highly thermal conductive sheet that have a coefficient of thermal expansion (CTE) that substantially matches (i.e., within ±10%) the CTE of the semiconductor chip. As a result of both heat and stress management, the electronic devices of the present application have improved performance and reliability. These and other aspects of the present application will be described in greater detail herein below.

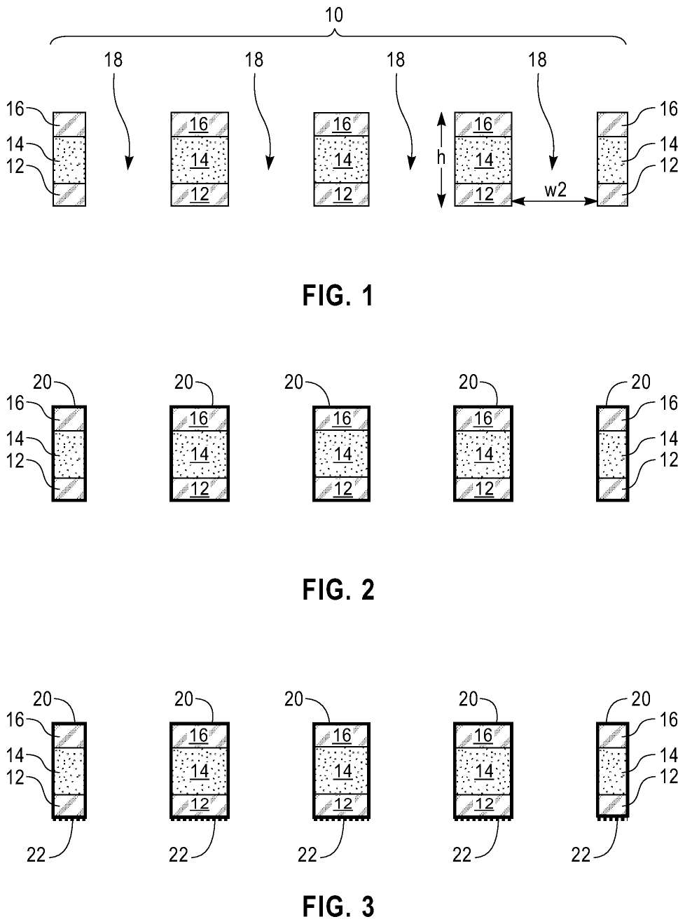

Reference is first made to FIGS. 1-7 which illustrate basic processing steps in accordance with a first embodiment of the present application that can be used in providing an electronic device that includes the electrically-insulating and highly thermal conductive sheet of the present application. Notably, FIG. 1 illustrates (through an enlarged cross sectional view) an electrically-insulating and highly thermal conductive sheet 10 that can be employed in one embodiment of the present application. As mentioned above, the electrically-insulating and highly thermal conductive sheet 10 is a perforated stack of a thermal conductive material-containing layer 14 sandwiched between a first ceramic layer 12 and a second ceramic layer 16. Although a single perforated stack of first ceramic layer 12, thermal conductive material-containing layer 14 and second ceramic layer 16 is described and illustrated, the present application contemplates embodiments in which the perforated stack is a composite structure that includes two or more stacks of first ceramic layer 12, thermal conductive material-containing layer 14 and second ceramic layer 16, each stack is located one above the other. As is shown, the electrically-insulating and highly thermal conductive sheet 10 contains a plurality of openings 18 that extend from an outermost surface of the first ceramic layer 12 to an outermost surface of the second ceramic layer; the openings 18 pass through the thermal conductive material-containing layer 14. That is, the openings extend from a first surface of the electrically-insulating and highly thermal conductive sheet 10 to a second surface of the electrically-insulating and highly thermal conductive sheet 10 that is opposite the first surface of the electrically-insulating and highly thermal conductive sheet 10.

The electrically-insulating and highly thermal conductive sheet 10 of the present application can have any shape including, for example, circular, square or rectangular. The electrically-insulating and highly thermal conductive sheet 10 of the present application has a total thickness, i.e., height (h). The height, h, is designed to provide an electrically-insulating and highly thermal conductive sheet 10 that includes from 50 to 90 percent of the thermal conductive material-containing layer 14 and the remainder of the electrically-insulating and highly thermal conductive sheet 10, up to 100 percent, includes from 10 to 50 percent of the first ceramic layer 12 and the second ceramic layer 16. Each opening 18 that is present in the electrically-insulating and highly thermal conductive sheet 10 has a width, w1.

The first ceramic layer 12 is composed of at least one electrically insulating, yet thermally conductive, material. Examples of electrically insulating, yet thermally conductive, materials that can be employed in providing the first ceramic layer 12 include, but are not limited to, aluminum nitride (AlN), silicon carbide (SiC) or diamond-like carbon (DLC). DLC is a class of amorphous carbon material that displays some of the typical properties of diamond. DLC contains significant amounts of sp³ hybridized carbon atoms. One example of a DLC material is tetrahedral amorphous carbon (ta-C). Ta—C can be considered to be the “pure” form of DLC, since it consists almost entirely of sp³ bonded carbon atoms. The DLC that can be used in the present application can contain fillers such as, for example, hydrogen, graphitic sp² carbon, and metals. The first ceramic layer 12 can be formed utilizing a deposition process including, but not limited, chemical vapor deposition (CVD), physical vapor deposition (PECVD), atomic layer deposition (ALD) and sputtering.

The second ceramic layer 16 is also composed of at least one electrically insulating, yet thermally conductive, material as mentioned above for the first ceramic layer 12. The at least one electrically insulating, yet thermally conductive, material which provides the second ceramic layer 16 can be compositionally the same as, or compositionally different from, the at least one electrically insulating, yet thermally conductive, material that provides the first ceramic layer 12. The second ceramic layer 16 can be formed utilizing a deposition process including, but not limited, CVD, PECVD, ALD and sputtering.

In some embodiments, the thermal conductive material-containing layer 14 that is sandwiched between the first ceramic layer 12 and the second ceramic layer 16 can be composed of an electrically conductive metal or an electrically conductive material alloy. Exemplary electrically conductive materials (i.e., metal or metal alloys) that can be use in providing the thermal conductive material-containing layer 14 include, but are not limited, copper (Cu), aluminum (Al), tungsten (W), cobalt (Co), ruthenium (Ru), rhodium (Rh), platinum (Pt) and alloys of Cu—Al. In other embodiments, the thermal conductive material-containing layer 14 is composed of graphite. In some embodiments, the thermal conductive material-containing layer 14 can include a mixture of electrically conductive materials and/or electrically conductive metal alloys and/or graphite. The thermal conductive material-containing layer 14 can be formed utilizing a deposition process including, but not limited, CVD, PECVD, ALD, sputtering and platting. In some embodiments, the thermal conductive material-containing layer 14 can have a thickness of 400 μm, while the combined thickness of the first ceramic layer 12 and the second ceramic layer 16 is 100 μm. Other thicknesses are possible provided that the electrically-insulating and highly thermal conductive sheet 10 includes from 50 to 90 percent of the thermal conductive material-containing layer 14 and the remainder of the electrically-insulating and highly thermal conductive sheet 10, up to 100 percent, includes from 10 to 50 percent of the first ceramic layer 12 and the second ceramic layer 16.

In one exemplary embodiment of the present application, the electrically-insulating and highly thermal conductive sheet 10 includes Cu as the thermal conductive material-containing layer 14 and AlN as the electrically insulating, yet thermally conductive, material for both the first ceramic layer 12 and the second ceramic layer 16.

The electrically-insulating and highly thermal conductive sheet 10 shown in FIG. 1 can be formed by first forming a non-perforated stack of the first ceramic layer 12, thermal conductive material-containing layer 14, and the second ceramic layer 16 by depositing the individual layers mentioned above. The electrically-insulating and highly thermal conductive sheet 10 is typically formed on a handler wafer (not shown). Next, openings 18 are formed into the non-perforated stack by laser etching or other like patterning processes. These steps provide the electrically-insulating and highly thermal conductive sheet 10. The handler wafer can be removed after forming the openings 18 into the non-perforated stack.

Referring now to FIG. 2, there is illustrated the electrically-insulating and highly thermal conductive sheet 10 shown in FIG. 1 after forming a dielectric coating 20 surrounding the electrically-insulating and highly thermal conductive sheet 10. The dielectric coating 20 is formed on all physically exposed surface of the electrically-insulating and highly thermal conductive sheet 10 including the outermost surface of both the first ceramic layer 12 and the second ceramic layer 16 and along the sidewall of each of the first ceramic layer 12, the thermal conductive material-containing layer 14, and the second ceramic layer 16 that is physically exposed in the openings 18. The dielectric coating 20 is composed of an electrical insulator material such as, for example, silicon nitride (SiN), silicon oxide (SiOx), silicon oxynitride (SiON) and any combination of these electrical insulator materials. The dielectric coating 20 can be formed utilizing a deposition process such as, for example, CVD, PECVD or ALD. The dielectric coating 20 that is formed can have a thickness of less than 250 nm.

In some embodiments not shown, a diffusion barrier layer can be formed on the dielectric coating 20. The diffusion barrier layer is composed of a diffusion barrier material that prevents the conductive material of the thermal conductive material-containing layer 14 from diffusing out of the electrically-insulating and highly thermal conductive sheet 10. Exemplary diffusion barrier materials that can be employed include, but are not limited to, tantalum (Ta), tantalum nitride (TaN), titanium (Ti), titanium nitride (TiN), tungsten (W) or tungsten nitride (WN). In some embodiments, the diffusion barrier layer can include a multilayered stack of diffusion barrier materials, e.g., a Ta/TaN or Ti/TiN multilayered stack. The diffusion barrier layer can be formed by a deposition process such as, for example, CVD, PECVD or ALD.

Referring now to FIG. 3, there is illustrated the dielectric coated electrically-insulating and highly thermal conductive sheet 10/20 shown in FIG. 2 after forming an adhesive layer 22 on one side of the dielectric coated electrically-insulating and highly thermal conductive sheet 10/22 In the illustrated embodiment, the adhesive layer 22 is formed on the dielectric coating 20 that is located on the outermost surface of the first ceramic layer 12. In embodiments of the present application, the adhesive layer 22 is composed of an adhesive material such as, for example, a polyimide adhesive. The adhesive layer 22 can be formed by printing or other like deposition processes.

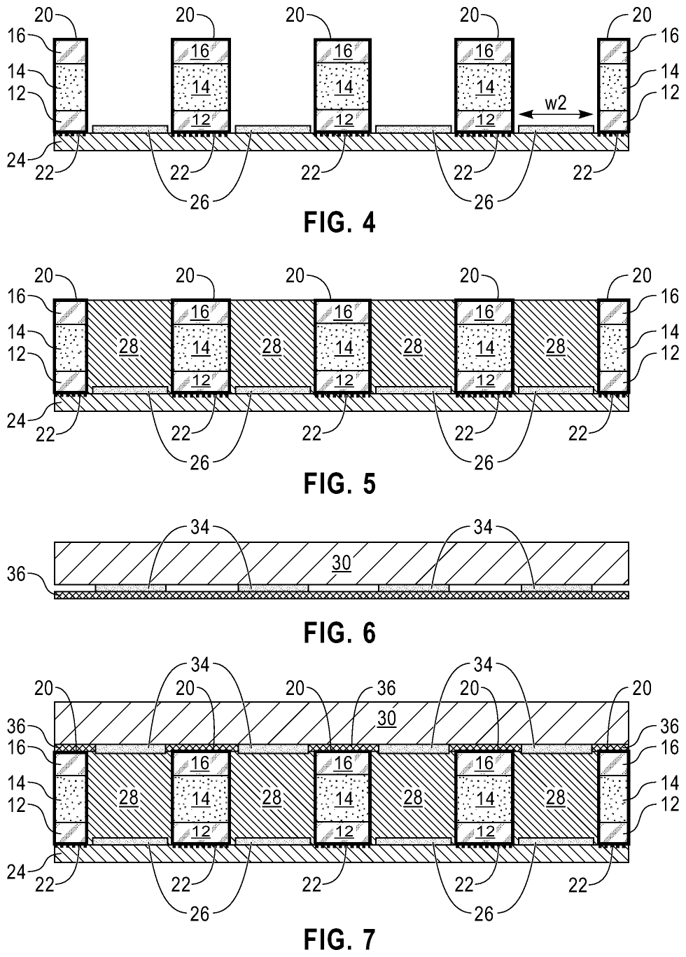

Referring now to FIG. 4, there is illustrated the dielectric coated electrically-insulating and highly thermal conductive sheet 10/20 shown in FIG. 3 after attaching the adhesive layer 22 of the dielectric coated electrically-insulating and highly thermal conductive sheet 10/20 to a laminate 24 containing metal bond pads 26. Although laminate 24 is shown as the packaging substrate, other packaging substrates such as, for example, organic imposers, silicon imposers, and glass interposers can be used in place of laminate 24.

In some embodiments, the laminate 24 is double-sided, while in other embodiments laminate 24 is multilayered. The laminate 24 is composed of a material or stack of materials that are well-known to those skilled in semiconductor packaging. In one embodiment, the laminate 24 is a printed circuit board.

The metal bond pads 26 are composed of copper or any other like metal bond pad material. The metal bond pads 26 can be formed utilizing techniques that are well-known in semiconductor packaging. The metal bond pads 26 can be formed, for example, by deposition (CVD, PECVD, ALD, plating, sputtering, etc.), of the metal bond pad material (e.g., a layer of Cu), followed by lithographic patterning. Each of the metal bond pads 26 is designed to have a width, w2, that is less than the width, w1, of the openings 18 such that the metal bond pads 26 that are formed on the laminate 24 (or other packaging substrate) can fit into the openings 18 of the electrically-insulating and highly thermal conductive sheet 10.

In the present application, the exemplary structure shown in FIG. 4 can be formed by aligning the bond pads 26 that are formed on the laminate 24 to fit into the openings 18, and thereafter attaching the laminate 24 to the adhesive layer 22 that is present on the dielectric coated electrically-insulating and highly thermal conductive sheet 10/20.

Referring now to FIG. 5, there is illustrated the exemplary structure shown in FIG. 4 after filling each of the openings 18 that are present in the dielectric coated electrically-insulating and highly thermal conductive sheet 10/20 with solder 28. Solder 28 can include any type of solder material that is typically used in semiconductor packaging technology. Notably, solder 28 can include, but is not limited to, lead-free solder compositions. The solder 28 can be formed into the openings 18 utilizing an injection molded solder technique or any other technique that can fill the openings 18 with solder. In some embodiments, a planarization process such as, for example, chemical mechanical polishing (CMP) can be used after filling the openings 18 with solder 28 so as to remove any solder that is formed outside of the openings 18. This planarization step typically stops on a surface of dielectric layer 20 that is present on the outermost surface of the second ceramic layer 16.

Referring now to FIG. 6, there is illustrated a semiconductor chip 30 that contains metal bond pads 34 and a non-conductive adhesive layer 36. Notably, the metal bond pads 34 are located on a surface of the semiconductor chip 30 and the non-conductive adhesive layer 36. The semiconductor chip 30 including a full sized chip or chiplets that have a size that is smaller than a full sized chip. The semiconductor chip 30 includes a front-end-of-the line (FEOL) level that contains one or more semiconductor devices such as, for example, transistors located on a frontside of a wafer, a middle-of-the-line (MOL) level that includes a MOL dielectric containing a plurality of frontside contact structures embedded therein, and a back-end-of-the-line (BEOL) level that includes one or more interconnect dielectric layers having electrically conductive wiring structures embedded therein. The semiconductor chip 30 can also include backside power rails and a backside power distribution network located on a backside of the wafer. The backside of the wafer is further from the MOL or BEOL than is the frontside of the wafer. The semiconductor die 30 that can be employed in the present application can be formed utilizing FEOL, MOL, BEOL, and backside wafer processing techniques that are well-known to those skilled in the art.

In some embodiments, the metal bond pads 34 are formed on the uppermost interconnect level of the BEOL structure that is present in the semiconductor chip 30. In other embodiments, the metal bond pads 34 are formed on the lowest metal level that is present on the backside of the wafer. The metal bond pads 34 are composed of copper or any other like metal bond pad material. The metal bond pads 34 can be formed utilizing techniques that are well-known in semiconductor packaging. The metal bond pads 34 can be formed, for example, by deposition (CVD, PECVD, ALD, plating, sputtering, etc.), of the metal bond pad material (e.g., a layer of Cu), followed by lithographic patterning. Each of the metal bond pads 34 is designed to have a width that is less than the width, w1, of the openings 18 such that the metal bond pads 34 do not extend beyond the width of the openings 18 of the electrically-insulating and highly thermal conductive sheet 10. Metal bond pads 34 are thus designed to be within the perimeter of the openings 18.

The non-conductive adhesive layer 36 is composed of a non-conductive (i.e., non-thermally conductive) adhesive material such as, for example, an epoxy or a polyimide. The non-conductive adhesive layer 36 can be applied to the metal bond pads 34 by hand or mechanical means.

Referring now to FIG. 7, there is illustrated, the exemplary structure shown in FIG. 5 after attaching the semiconductor chip 30 shown in FIG. 6 thereto. Notably, the attaching includes bringing the non-conductive adhesive layer 36 of the structure shown in FIG. 6 in intimate physical contact with solder 28 and the dielectric coated electrically-insulating and highly thermal conductive sheet 10/20 shown in FIG. 5, and thereafter heating the combined structures under pressure to form a bond between the two structures. Note that during this step of the present application, the non-conductive adhesive layer 36 flows into the gaps that are located between the metal bond pads 34. As illustrated in FIG. 7, solder 38 is in direct contact with one of metal bond pads 34 that is located on the semiconductor chip 30 and with one of metal bond pads 26 that is located on the laminate 24. As is also illustrated in FIG. 7, the non-conductive adhesive layer 36 forms a bond with the dielectric coating 20 that is present on outermost surface of the second ceramic layer 16 of the electrically-insulating and highly thermal conductive sheet 10.

FIG. 7 illustrated one exemplary electronic device of the present application. Notably, the electronic device illustrated in FIG. 7 includes electrically-insulating and highly thermal conductive sheet 10 having a first surface and a second surface opposite the first surface, wherein the electrically-insulating and highly thermal conductive sheet 10 is a perforated stack of thermal conductive material-containing layer 14 sandwiched between first ceramic layer 12 and second ceramic layer 16. The electronic device further includes packaging substrate (e.g., laminate 24) located on the first surface of the electrically-insulating and highly thermal conductive sheet 10, and at least one semiconductor chip 30 located on the second surface of the electrically-insulating and highly thermal conductive sheet 10. The electrically-insulating and highly thermal conductive sheet 10 has a plurality of openings 18 that extend from the first surface of the electrically-insulating and highly thermal conductive sheet 10 to the second surface of the electrically-insulating and highly thermal conductive sheet 10, and in this embodiment, each of the openings 18 is filled with solder 28.

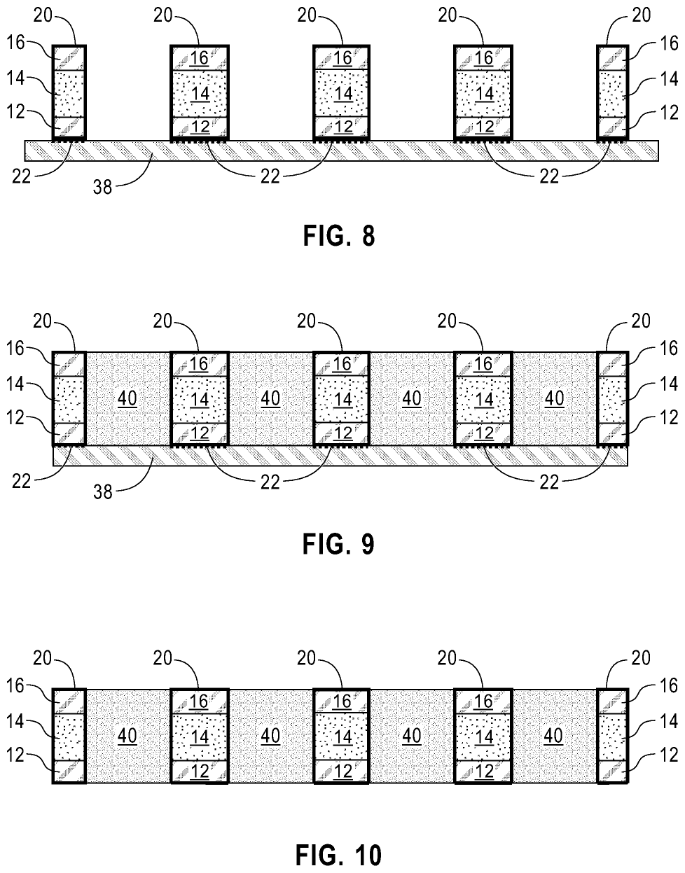

Reference is now to FIGS. 8-13 which illustrate basic processing steps in accordance with a second embodiment of the present application that can be used in providing an electronic device that includes the electrically-insulating and highly thermal conductive sheet of the present application. Notably, the second embodiment begins by first providing the dielectric coated electrically-insulating and highly thermal conductive sheet 10/20 containing the adhesive layer 22 as shown in FIG. 3. Next, and as is shown in FIG. 8, a temporary metal sheet 38 is formed in contact with the adhesive layer 22. The temporary metal sheet 38 is composed of an electrically conductive metal or electrically conductive metal alloy as mentioned above for metal bond pads 26. In one example, the temporary metal sheet 28 is composed of copper. The temporary metal sheet 38 is used as a seeding surface for the electrically conductive metal-containing material to be subsequently formed.

Referring now to FIG. 9, there is illustrated the exemplary structure shown in FIG. 8 after filling each of the openings 18 that are present in the dielectric coated electrically-insulating and highly thermal conductive sheet 10/20 with an electrically conductive metal-containing material 40. In some embodiments, the electrically conductive metal-containing material 40 is composed of an electrically conductive material such as, for example, copper, which matches the electrically conductive material that provides the temporary metal sheet 38. The electrically conductive metal-containing material 40 can be filled into each of the openings 18 by a deposition process such as, for example, electroplating. A planarization process such as, for example, CMP, can follow the deposition of the electrically conductive material that provides the electrically conductive metal-containing material 40.

Referring now to FIG. 10, there is illustrated the exemplary structure shown in FIG. 9 after removing the temporary metal sheet 38. The temporary metal sheet 38 can be removed utilizing any material removal process that is capable of removing the temporary metal sheet 38 from the structure. In one example, a fly-cut process can be used to remove the temporary metal sheet 38. In another example, CMP can be used to remove the temporary metal sheet 38. It is noted that during the removal of the temporary metal sheet 38, adhesive layer 22 can also be removed from the structure; see, for example, FIG. 10. In other embodiments, the adhesive layer 22 can remain after the removal of the temporary metal sheet 38.

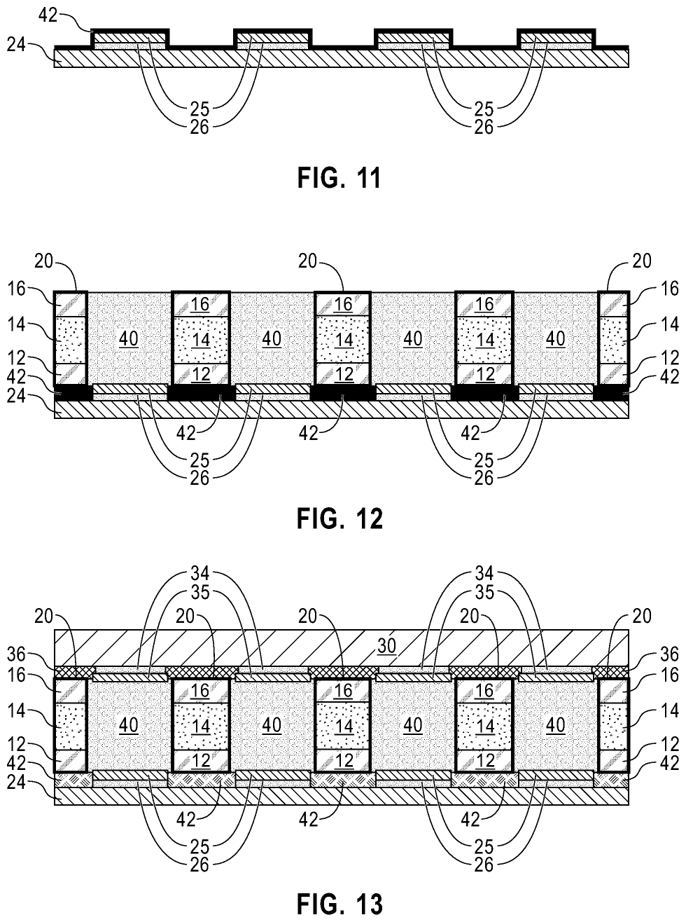

Referring now to FIG. 11, there is illustrated a laminate 24 that contains metal bond bands 26 and a non-conductive adhesive layer 42. In some embodiments, and as is illustrated in FIG. 11, solder 25 can be present between a topmost surface of each metal bond pad 26 and a bottommost surface of non-conductive adhesive layer 42. Laminate 24 and metal bond pads 26 are as defined above for the first embodiment of the present application. It is noted that laminate 24 can be replaced by other packaging substrates as noted above in the first embodiment of the present application. The non-conductive adhesive layer 42 is the same as non-conductive adhesive layer 36 described above in the first embodiment of the present application.

The exemplary structure shown in FIG. 11 can be formed by first providing the laminate 24, and then forming metal bond pads 26 on a surface of the laminate 24. The metal bond pads 26 can be formed utilizing the process mentioned above in the previously embodiment of the present application. After forming the metal bond pads 26, solder 25 is formed on the metal bond pads. Solder 25 includes one of the solder materials mentioned above for solder 28. The non-conductive adhesive layer 42 is the applied on the physically exposed surface of the solder 25, metal bond pads 26 and laminate 24. The application of the non-conductive adhesive layer 42 is the same as described above for non-conductive adhesive layer 36.

Referring now to FIG. 12, there is illustrated the exemplary structure shown in FIG. 10 after attaching the laminate 24 shown in FIG. 11 thereto. Notably, the attaching includes aligning the solder 25 and the metal bond pads 26 with the electrically conductive metal-containing material 40 filled openings 18, bringing the non-conductive adhesive layer 42 of the structure shown in FIG. 11 in intimate physical contact with a bottommost surface of the structure shown in FIG. 10, and thereafter heating the combined structures under pressure to form a bond between the two structures. Note that during the this step of the present application, the non-conductive adhesive layer 42 flows from atop the metal bond pads 26. As is illustrated in FIG. 12, solder 25 is in direct contact with one of electrically conductive metal-containing material 40 filled openings 18, and the non-conductive adhesive layer 42 forms a bond with the dielectric coating 20 that is present on outermost surface of the first ceramic layer 16 of the electrically-insulating and highly thermal conductive sheet 10.

Referring now to FIG. 13, there is illustrated the exemplary structure shown in FIG. 12 after attaching a semiconductor chip 30 as is shown in FIG. 6 thereto. The attaching of semiconductor chip 50 in this embodiment of the present application is the same as the attaching of the semiconductor chip 50 in the previous embodiment of the present application. Note that in FIG. 13, the solder 35 is in direct contact with one of electrically conductive metal-containing material 40 filled openings 18, and the non-conductive adhesive layer 36 forms a bond with the dielectric coating 20 that is present on outermost surface of the second ceramic layer 16 of the electrically-insulating and highly thermal conductive sheet 10.

FIG. 13 illustrated another exemplary electronic device of the present application, Notably, the electronic device illustrated in FIG. 13 includes electrically-insulating and highly thermal conductive sheet 10 having a first surface and a second surface opposite the first surface, wherein the electrically-insulating and highly thermal conductive sheet 10 is a perforated stack of thermal conductive material-containing layer 14 sandwiched between first ceramic layer 12 and second ceramic layer 16. The electronic device further includes packaging substrate (e.g., laminate 24) located on the first surface of the electrically-insulating and highly thermal conductive sheet 10, and at least one semiconductor chip 30 located on the second surface of the electrically-insulating and highly thermal conductive sheet 10. The electrically-insulating and highly thermal conductive sheet 10 has a plurality of openings 18 that extend from the first surface of the electrically-insulating and highly thermal conductive sheet 10 to the second surface of the electrically-insulating and highly thermal conductive sheet 10, and in this embodiment, each of the openings 18 is filled with an electrically conductive material with electrically conductive metal-containing material 40 (i.e., an electrically conductive metal or an electrically conductive metal alloy).

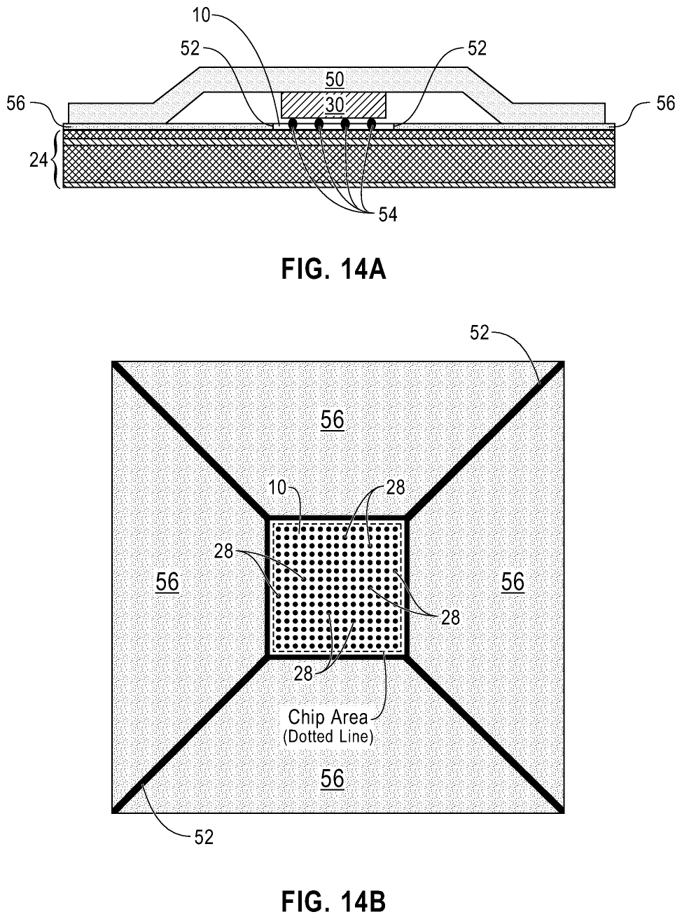

Reference is now made to FIG. 14A, which illustrate an electronic device that contains an electrically-insulating and highly thermal conductive sheet 10 in accordance with the present application. FIG. 14B is a top-down view showing the interconnect level containing the electrically-insulating and highly thermal conductive sheet 10 of the device shown in FIG. 14A. Notably, the electronic device illustrated in FIGS. 14A-14B includes laminate 24 (in this exemplary device laminate 24 is illustrated as a multilayered laminate). Attached to the laminate 24 is the electrically-insulating and highly thermal conductive sheet 10. In this embodiments, the openings in the electrically-insulating and highly thermal conductive sheet 10 are filled with solder 28 (See, FIG. 14B).

The electronic device further includes a semiconductor chip 50 attached by solder balls 54 (solder balls 54 include any well-known solder material including those described herein) to the electrically-insulating and highly thermal conductive sheet 10; the electrically-insulating and highly thermal conductive sheet 10 provides an interconnection of the semiconductor chip 50 to the laminate 24. The electronic device illustrated in FIGS. 14A-14B further includes a thermal conductive adhesive layer 52 (such as a silver adhesive) located on a sidewall of the electrically-insulating and highly thermal conductive sheet 10, a Cu layer 56 (or other electrically conductive material as defined above) located adjacent to the adhesive layer 52 and a lid 50 located on top of the semiconductor chip 50 and extending onto a surface of the Cu layer 56. In some embodiments, lid 50 can be composed of a heat spreader material. In some embodiments, lid 50 is composed of Cu. In FIG. 14B, the dotted line shows that chip area; note that the area of the electrically-insulating and highly thermal conductive sheet 10 is slightly larger than the chip area.

The electronic device shown in FIGS. 14A-14B can be formed by first fabricating an electrically-insulating and highly thermal conductive sheet 10 having opening 18 such as is shown in FIG. 3. The electrically-insulating and highly thermal conductive sheet 10 having opening 18 is then aligned and attached to the laminate 24 by adhesive layer 22 (see description above regarding the formation of the exemplary structure shown in FIG. 4). The openings 18 in the electrically-insulating and highly thermal conductive sheet 10 are then filled with solder 38 (see description above regarding the formation of the exemplary structure shown in FIG. 5). The adhesive 52 is then applied by means well-known to those skilled in the art, and thereafter Cu layer 56 is placed onto the structure and curing is then performed on the structure.

Semiconductor chip 50 is then attached to a surface of the electrically-insulating and highly thermal conductive sheet 10 that is opposite a surface of the electrically-insulating and highly thermal conductive sheet 10 that is attached to the laminate 24 (see description above regarding the formation of the exemplary structure shown in FIGS. 6 and 7). Lid 50 is then formed using techniques well-known to those skilled in the art.

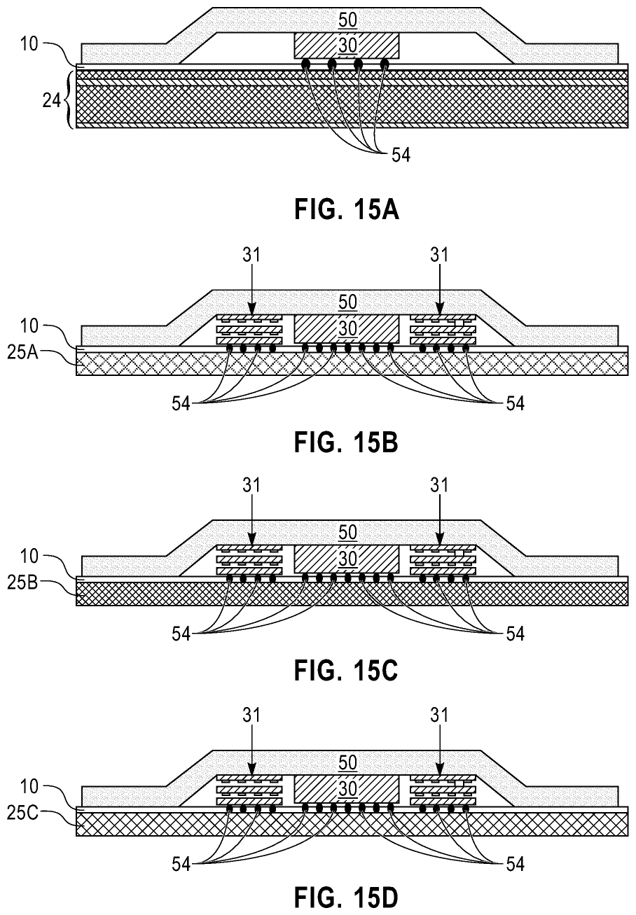

Reference is now made to FIGS. 15A, 15B, 15C and 15D, which illustrate other electronic devices that contain an electrically-insulating and highly thermal conductive sheet 10 in accordance with the present application, in these electronic devices a heat spreader can be used for cooling. The electrically-insulating and highly thermal conductive sheet 10 of each of the illustrated electronic devices contains openings 18 (not shown) that can be filled with either solder 28 or electrically conductive metal-containing material 40. Notably, the electronic device illustrated in FIG. 15A includes laminate 24 attached to one surface of the electrically-insulating and highly thermal conductive sheet 10, and a semiconductor chip 30 attached to another surface of the electrically-insulating and highly thermal conductive sheet 10. In this embodiment, the semiconductor chip 30 can be a high power chip. The term high power chip denotes a chip that has a power or greater than 10 W/cm². The electronic device of FIG. 15A also includes solder balls 54 and lid 50. In this embodiment lid 50 is composed of a heat spreader material such as, for example, Cu, Al or SiC.

The electronic device shown in FIG. 15B includes an organic interposer 25A, attached to one surface of the electrically-insulating and highly thermal conductive sheet 10, and a semiconductor chip 30 (in this embodiment semiconductor chip 30 can be a higher power chip as defined above) and a pair of stacked semiconductor chips 31 attached to another surface of the electrically-insulating and highly thermal conductive sheet 10. The electronic device of FIG. 15B also includes solder balls 54 and lid 50. In this embodiment lid 50 is composed of a heat spreader material. In FIGS. 15B-15D, the stacked semiconductor chips 31 include a plurality of semiconductor chips that are stacked one atop the another and an attached via solder balls.

The electronic device shown in FIG. 15C includes a silicon interposer 25B, attached to one surface of the electrically-insulating and highly thermal conductive sheet 10, and a semiconductor chip 30 (in this embodiment semiconductor chip 30 can be a higher power chip as defined above) and a pair of stacked semiconductor chips 31 attached to another surface of the electrically-insulating and highly thermal conductive sheet 10. The electronic device of FIG. 15C also includes solder balls 54 and lid 50. In this embodiment lid 50 is composed of a heat spreader material.

The electronic device shown in FIG. 15D includes a glass interposer 25C, attached to one surface of the electrically-insulating and highly thermal conductive sheet 10, and a semiconductor chip 30 (in this embodiment semiconductor chip 30 can be a higher power chip as defined above) and a pair of stacked semiconductor chips 31 attached to another surface of the electrically-insulating and highly thermal conductive sheet 10. The electronic device of FIG. 15D also includes solder balls 54 and lid 50. In this embodiment lid 50 is composed of a heat spreader material.

Each of the electronic devices illustrated in FIGS. 15A-15D can be formed utilizing the basic processing steps described herein. In the electronic devices shown in FIGS. 15A-15D cooling is performed using a lid 50 that is composed of a heat spreader material.

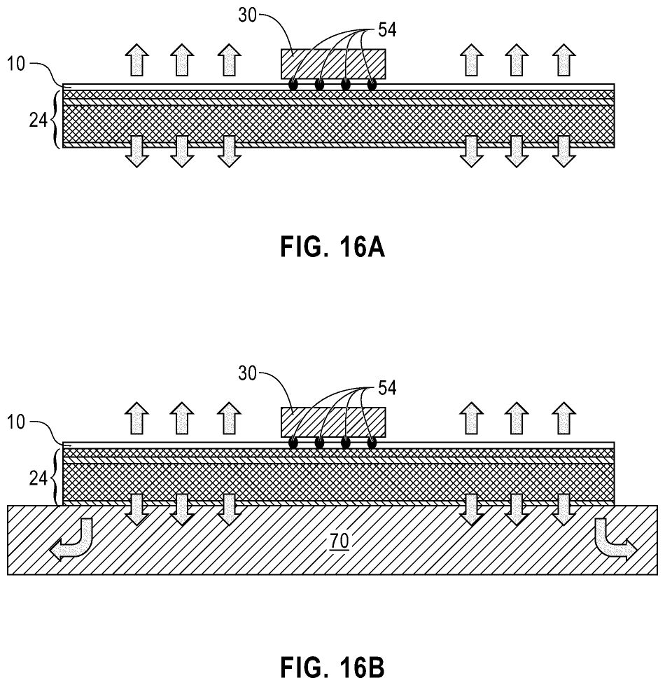

Reference is now made to FIGS. 16A and 16B are cross sectional views illustrating other electronic devices that contain an electrically-insulating and highly thermal conductive sheet in accordance with the present application, in these electronic devices heat is removed via the laminate.

Each of the electronic devices illustrated in FIGS. 16A-16B can be formed utilizing the basic processing steps described herein. Notably, the electronic device illustrated in FIG. 16A includes a laminate 24 attached to one surface of the electrically-insulating and highly thermal conductive sheet 10 (having openings that are filled with solder or an electrically conductive material as defined above), and a semiconductor chip 30 (in this embodiment semiconductor chip 30 can be a lower power chip) attached to another surface of the electrically-insulating and highly thermal conductive sheet 10. The term “low power chip” denotes a chip have a power of 10 W/cm² or less. The electronic device of FIG. 16A also includes solder balls 54. The electronic device illustrated in FIG. 16B is similar to the one depicted in FIG. 16A except that laminate 24 is attached to a chassis 70. Since low power semiconductor chips are used in the electronic devices illustrated in FIGS. 16A and 16B heat can be removed from the laminate itself. Notably, the arrow shown in FIGS. 16A and 16B depict the direction of heat flow in the electronic devices.

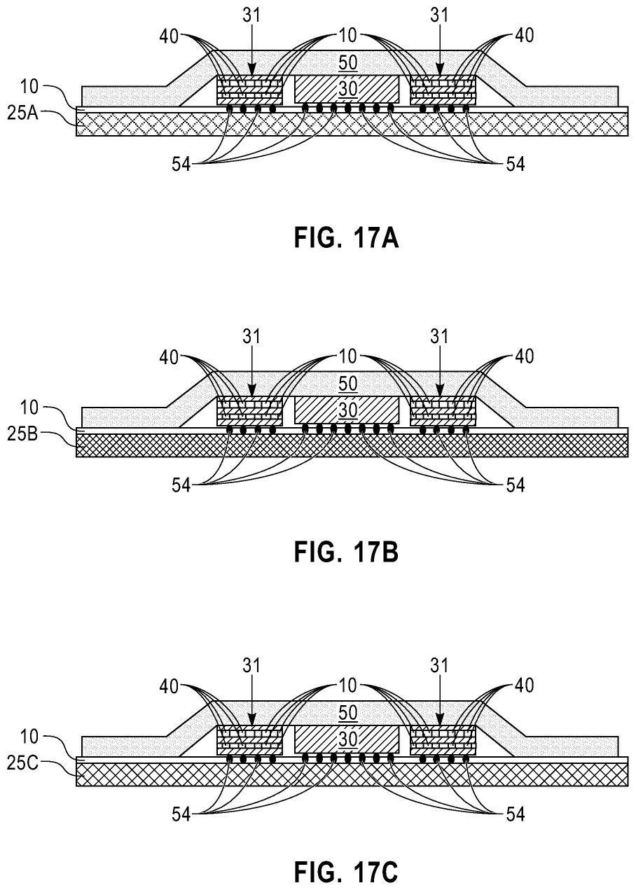

Reference is now made FIGS. 17A, 17B and 17C which illustrates 3D stacked die electronic devices that contain an electrically-insulating and highly thermal conductive sheet 10 in accordance with the present application, in these devices the electrically-insulating and highly thermal conductive sheet mitigates hot spots. The electrically-insulating and highly thermal conductive sheet 10 of each of the illustrated electronic devices in FIGS. 17A-17C contains openings 18 that can be filled with electrically conductive metal-containing material 40. Notably, the electronic device illustrated in FIG. 17A includes an organic interposer 25A attached to one surface of the electrically-insulating and highly thermal conductive sheet 10 (containing filled openings as mentioned above), and a semiconductor chip 30 and a pair of stacked semiconductor chips 31 attached to another surface of the electrically-insulating and highly thermal conductive sheet 10. The electronic device of FIG. 1A also includes solder balls 54 and lid 50, both as defined above. In FIGS. 17A-17C, the stacked semiconductor chips 31 include a plurality of semiconductor chips that are stacked one atop the another and attached via electrically-insulating and highly thermal conductive sheet 10 containing openings are filled with electrically conductive metal-containing material 40.

The electronic device shown in FIG. 17B is the same as that shown in FIG. 17A except that a silicon interposer 25B is used instead of the organic interposer 25A illustrated in FIG. 17A. Likewise, the electronic device shown in FIG. 17C is the same as that shown in FIG. 17A except that a glass interposer 25C is used instead of the organic interposer 25A illustrated in FIG. 17A. Each of the electronic devices illustrated in FIGS. 17A-17C can be formed utilizing the basic processing steps described herein. In the electronic devices shown in FIGS. 17A-17C, hot spots are mitigated due to the presence of the electrically-insulating and highly thermal conductive sheet 10 of the present application being located at the interconnect level.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An electronic device comprising:
an electrically-insulating and highly thermal conductive sheet having a first surface and a second surface opposite the first surface, wherein the electrically-insulating and highly thermal conductive sheet is a perforated stack of a thermal conductive material-containing layer sandwiched between a first ceramic layer and a second ceramic layer;
a packaging substrate located on the first surface of the electrically-insulating and highly thermal conductive sheet; and
at least one semiconductor chip located on the second surface of the electrically-insulating and highly thermal conductive sheet.

2. The electronic device of claim 1, wherein the electrically-insulating and highly thermal conductive sheet has a plurality of openings that extend from the first surface of the electrically-insulating and highly thermal conductive sheet to the second surface of the electrically-insulating and highly thermal conductive sheet.

3. The electronic device of claim 2, wherein each of the openings is filled with solder.

4. The electronic device of claim 2, wherein each of the openings is filled with an electrically conductive metal or an electrically conductive metal alloy.

5. The electronic device of claim 1, wherein the first ceramic layer and the second ceramic layer are both composed of a same electrically insulating, yet thermally conductive, material.

6. The electronic device of claim 1, wherein the first ceramic layer and the second ceramic layer are both composed of different electrically insulating, yet thermally conductive, material.

7. The electronic device of claim 1, wherein the thermal conductive material-containing layer is composed of an electrically conductive metal, electrically conductive metal alloy or graphite.

8. The electronic device of claim 1, wherein the first ceramic layer and the second ceramic layer are both composed of aluminum nitride (AlN), and the thermal conductive material-containing layer is composed of copper (Cu).

9. The electronic device of claim 1, further comprising a dielectric coating surrounding the perforated stack.

10. The electronic device of claim 1, further comprising a first non-conductive adhesive layer contacting the first ceramic layer and a portion of the packaging substrate, and a second non-conductive adhesive layer contacting the second ceramic layer and a portion of the semiconductor chip.

11. The electronic device of claim 2, further comprising first metal bond pads located on the packaging substrate and second metal bond pads located on the semiconductor chip, wherein the first metal bond pads and the second metal bond pads are aligned with each of the openings.

12. The electronic device of claim 11, further comprising a first solder layer located on each of the first metal bond pads and a second solder layer located on each of the second metal bond pads, wherein the first metal bond pads, the first solder layer, the second metal bond pads and the second solder layer are aligned with each of the openings.

13. The electronic device of claim 1, wherein the packaging substrate comprises a laminate, an organic interposer, a silicon interposer or a glass interposer.

14. The electronic device of claim 1, wherein the semiconductor chip comprises a plurality of stacked semiconductor chips.

15. The electronic device of claim 14, wherein each stacked chip of the plurality is spaced apart by another electrically-insulating and highly thermal conductive sheet, wherein the another electrically-insulating and highly thermal conductive sheet is another perforated stack of another thermal conductive material-containing layer sandwiched between another first ceramic layer and another second ceramic layer.

16. The electronic device of claim 1, further comprising a lid located on top of the semiconductor chip.

17. The electronic device of claim 16, wherein the lid is composed of a thermal spreader material.

18. The electronic device of claim 1, wherein the electrically-insulating and highly thermal conductive sheet comprises from 50 to 90 percent of the thermal conductive material-containing layer and the remainder of the electrically-insulating and highly thermal conductive sheet, up to 100 percent, comprises from 10 to 50 percent of the first ceramic layer and the second ceramic layer.

19. The electronic device of claim 1, wherein the semiconductor chip is a high power semiconductor chip.

20. The electronic device of claim 1, wherein the semiconductor chip is a low power semiconductor chip.
